(19) United States
(12) Patent Application Publication
(10) Pub. No.: US 2011/0010932 A1
(43) Pub. Date: Jan. 20, 2011

(54) WIRING BOARD, SEMICONDUCTOR DEVICE HAVING WIRING BOARD, AND METHOD OF MANUFACTURING WIRING BOARD

(75) Inventors: Masato TANAKA, Nagano-shi (JP); Fumihiko Hayano, Nagano-shi (JP); Toru Hizume, Nagano-shi (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD., Nagano-shi (JP)

(21) Appl. No.: 12/891,071

(22) Filed: Sep. 27, 2010

Related U.S. Application Data
(62) Division of application No. 12/275,723, filed on Nov. 21, 2008.

(30) Foreign Application Priority Data
Nov. 22, 2007 (JP) 2007-302994

(51) Int. Cl. H05K 3/00

(52) U.S. Cl. 29/830

(57) ABSTRACT

The present disclosure relates to a method of manufacturing a wiring board. The method includes: (a) preparing a first board having a pad; (b) providing an insulating member on the first board, wherein a size of the insulating member is larger than that of the first board, when viewed from the top; (c) forming a via in the insulating member such that the via is directly connected to the pad; and (d) repeatedly forming a wiring layer and an insulating layer on the insulating member in which the via is formed, thereby forming a second board.

This application claims priority from Japanese Patent Application No. 2007-302994, filed on Nov. 22, 2007, the entire contents of which are incorporated by reference herein.

### BACKGROUND

1. Technical Field

The present disclosure relates to a wiring board, a semiconductor device having the wiring board, and a method of manufacturing the wiring board. More particularly, the present disclosure relates to a wiring board in which a first board and a second board are built-up, a semiconductor device having the wiring board, and a method of manufacturing the wiring board.

2. Related Art

In recent years, with a high density semiconductor device, a wiring board mounted on the semiconductor device has also been subjected to finer design rules and high density design rules. FIG. 11 shows a wiring board that deals with the high density semiconductor device in the related art.

The wiring board shown in FIG. 11 is a build-up board 100. In the build-up board 100, build-up layers 102 and 103 are provided on both sides of a core layer 101 made of prepreg. Each of the build-up layers 102 and 103 includes wiring layers and insulting layers, which are provided alternately. The respective wiring layers are interlayer-connected to each other through vias. The build-up layers 102 and 103 are electrically connected by through holes formed in the core layer 101.

In the build-up board 100 shown in FIG. 11, a semiconductor device is mounted on the build-up layer 102 and the build-up layer 103 is mounted on a mounting board such as a mother board. At this time, the build-up layers 102 and 103 can be subjected to fine process and thus the wiring layer can be formed with high precision. Thus, the fine pitches of pads connected to the semiconductor element can be performed and thus it is possible to deal with a high density semiconductor device.

By the way, as a method of manufacturing the build-up board 100 (wiring board), a plurality of wiring boards are formed on a substrate having a wide area for taking out multiple wiring boards and then the wiring boards are divided into pieces. Thus, wiring boards are manufactured. The manufacturing cost per the wiring board can be reduced by lessening the size of the wiring board.

However, the semiconductor element is mounted on an upper surface of the build-up board 100 (i.e., an upper surface of the build-up layer 102) and a lower surface of the build-up board 100 (i.e., a lower surface of the build-up layer 103) is connected to the mounting board such as a mother board. When only the semiconductor element is mounted on the build-up board 100, the build-up board 100 can be miniaturized by applying the whole build-up board 100 into finer design rules.

However, a mounting board such as a mother board is a multilayer printed circuit substrate and pitches of pads formed on the mounting substrate are much larger than the electrode pitches of the semiconductor element, and thus the size of the build-up board 100 cannot simply be reduced in light of connection to the mounting board.

As means for solving the above problem, there has been proposed a composite wiring board. The composite wiring board includes a first board (interposer) having fine wirings and a second board having connection pitches capable of mounting the wiring board on the mother board, and the first and second boards are boned to each other electrically and mechanically. (see e.g., JP-A-2005-011883)

FIGS. 12A and 12B show an example of the composite wiring board. FIG. 12A shows a wiring board 110 in which a silicon interposer 107 (first board) is mounted on the build-up board 100 (second board) electrically and mechanically. FIG. 12B shows a semiconductor device 120 in which a semiconductor element 111 is mounted on the wiring board 110.

The silicon interposer 107 can be formed with high precision and therefore can be compatible with the electrode pitches of the semiconductor element 111. Since the silicon interposer 107 is not influenced by the precision of the mounting board such as a mother board, the dimension of the silicon interposer 107 can be lessened. Therefore, multiple silicon interposers 107 can be produced in manufacturing process and thus the manufacturing cost can be reduced.

Further, the build-up layer 102 of the build-up board 100 is formed with a high precision for enabling the build-up board 100 to be connected to the silicon interposer 107 and the build-up layer 103 can be formed with pads at wide pitches for enabling the build-up board 100 to be connected to the mounting board such as a mother board.

Accordingly, by employing the structure in which the build-up board 100 and the silicon interposer 107 are mounted, the wiring board 110 which can maintain connectivity between the semiconductor element 111 and the mounting board such as a mother board can be provided at relatively low cost.

However, in the related art wiring board 110 shown in FIGS. 12A and 12B, the build-up board 100 and the silicon interposer 107 are solder-bonded to each other through bumps 108 and an underfill resin 109 is provided between the build-up board 100 and the silicon interposer 107.

Thus, the related art wiring board 110 requires the bumps 108 and the underfill resin 109 when the silicon interposer 107 and the build-up board 100 are bonded to each other. As a result, the number of components increases.

In manufacturing the wiring board 110, an interposer mounting step and a filling step of the underfill resin 109 become necessary and the manufacturing process becomes complicated. Further, the facilities for mounting the silicon interposer 107 on the build-up board 100 and filling the underfill resin 109 become necessary, and thus the facility cost increases.

### SUMMARY OF THE INVENTION

Exemplary embodiments of the present invention address the above disadvantages and other disadvantages not described above. However, the present invention is not required to overcome the disadvantages described above, and thus, an exemplary embodiment of the present invention may not overcome any of the problems described above.

According to a wiring board, a semiconductor device having the wiring board, and a method of manufacturing the wiring board, it is possible to manufacture the wiring board at low cost, and also it is possible to maintain connectivity between a semiconductor element and a mounting substrate without increasing components or manufacturing processes.

According to one or more aspects of the present invention, there is provided a wiring board. The wiring board includes: a first board which comprises a pad; and a second board which comprises a via, wherein the first board is mounted on the second board such that the via and the pad are directly connected to each other.

According to one or more aspects of the present invention, the first board is bonded onto the second board through an adhesive in a region except for a connection region of the pad and the via.

According to one or more aspects of the present invention, a size of the first board is smaller than that of the second board, when viewed from the top.

According to one or more aspects of the present invention, the wiring board further includes: a reinforcing member provided on the second board such that the reinforcing member surrounds the first board.

According to one or more aspects of the present invention, there is provided a semiconductor device. The semiconductor device includes: a wiring board including: a first board which has a pad; and a second board which has a via, wherein the first board is mounted on the second board such that the via and the pad are directly connected to each other; and a semiconductor element mounted on the first board.

According to one or more aspects of the present invention, the second board further includes an external connection pad connected to the via, and the second board is mounted on a mother board through an external connection terminal provided on the external connection pad.

According to one or more aspects of the present invention, there is provided a method of manufacturing a wiring board. The method includes: (a) preparing a first board having a pad; (b) providing an insulating member on the first board, wherein a size of the insulating member is larger than that of the first board, when viewed from the top; (c) forming a via in the insulating member such that the via is directly connected to the pad; and (d) repeatedly forming a wiring layer and an insulating layer on the insulating member in which the via is formed, thereby forming a second board.

According to one or more aspects of the present invention, the insulating member is a resin film, and step (b) includes: bonding the resin film onto the first board through an adhesive.

According to one or more aspects of the present invention, step (b) includes: placing the first board in a mold; and forming the insulating member on the first board by molding a resin.

According to one or more aspects of the present invention, step (c) includes: forming a via hole in a portion of the insulating member corresponding to the pad; and forming the via in the via hole by plating.

Other aspects and advantages of the present invention will be apparent from the following description, the drawings, and the claims.

### BRIEF DESCRIPTION OF THE DRAWINGS

In the accompanying drawings:

FIG. 1 is a sectional view of a wiring board according to an exemplary embodiment of the present invention;

FIG. 2 is a sectional view of a semiconductor device according to the exemplary embodiment of the present invention;

FIG. 3 is a sectional view showing a first modified example of the wiring board according to the exemplary embodiment of the present invention;

FIG. 4 is a sectional view showing a second modified example of the wiring board according to the exemplary embodiment of the present invention;

FIG. 5 is a sectional view showing a third modified example of the wiring board according to the exemplary embodiment of the present invention;

FIG. 6 is a sectional view showing a fourth modified example of the wiring board according to the exemplary embodiment of the present invention;

FIGS. 7A to 7E are views (#1) showing a method of manufacturing the wiring board according to the exemplary embodiment of the present invention;

FIGS. 8A to 8D are views (#2) showing the method of manufacturing the wiring board according to the exemplary embodiment of the present invention;

FIGS. 9A to 9D are sectional views showing a step of bonding a via connection pad and a connection via in an enlarged manner;

FIGS. 10A to 10C are views showing a modified example in which an insulating member is provided on a first board;

FIG. 11 is a sectional view (#1) showing a wiring board in the related art; and

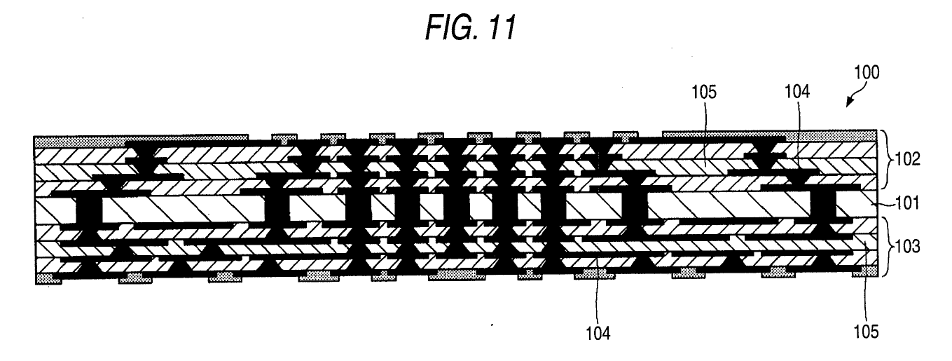

FIGS. 12A and 12B are sectional views (#2) showing a wiring board in the related art.

### DETAILED DESCRIPTION OF EXEMPLARY EMBODIMENTS OF THE INVENTION

Exemplary embodiments of the present invention will be described with reference to the drawings hereinafter.

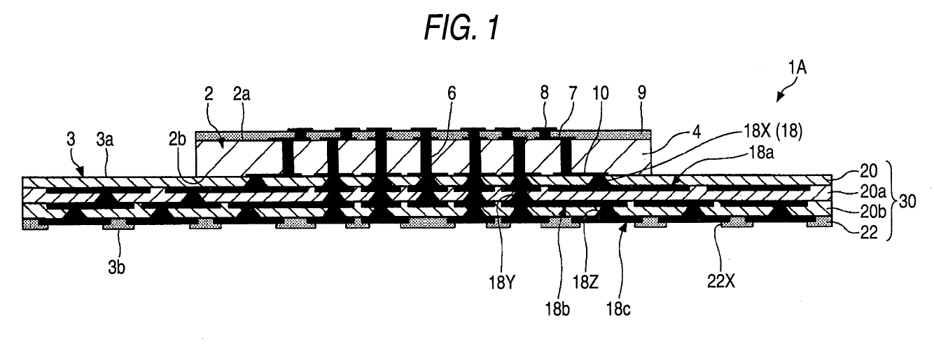

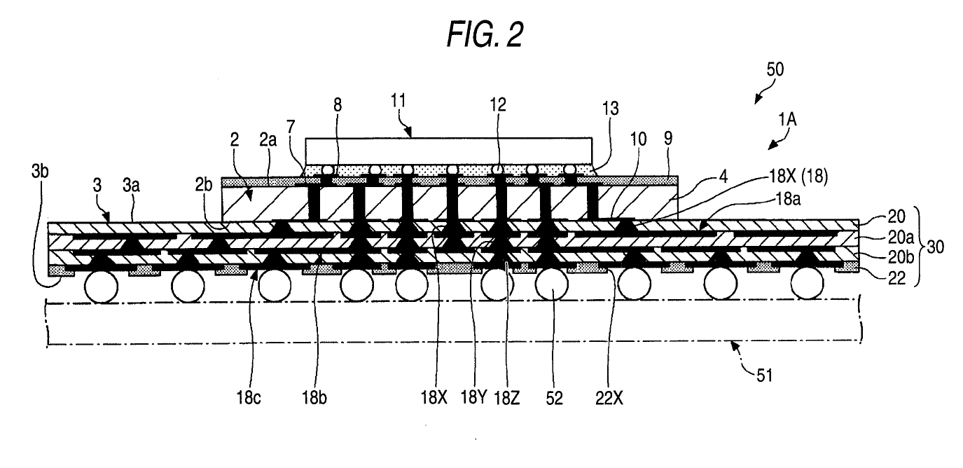

FIG. 1 shows a wiring board 1A according to an exemplary embodiment of the present invention. FIG. 2 shows a semiconductor device 50 having the wiring board 1A. The wiring board 1A, if roughly classified, includes a first board 2 and a second board 3. The first board 2 and the second board 3 are mounted.

The first board 2 is a silicon interposer and is a rectangular board having a size of 20 mm×20 mm, for example, when viewed from the top. In the exemplary embodiment, an example using the silicon interposer as the first board 2 will be described, but an organic substrate or a ceramic substrate can also be used in place of the silicon interposer if high processing accuracy can be performed.

The first board 2 includes a silicon substrate 4, through electrodes 6, upper wirings 7, chip connection pads 8, via connection pads 10, or the like.

The through electrode 6 is formed to pass through the silicon substrate 4, and is made of copper, for example. The upper wiring 7, the chip connection pads 8 and an insulating film 9 are formed on the upper surface of the silicon substrate 4. The chip connection pads 8 are formed at positions corresponding to the electrode positions of a semiconductor element 11.

The upper wiring 7 functions as rewiring for connecting the chip connection pads 8 and the through electrodes 6. The insulating film 9 is an SiO₂ film, for example, and is formed except for the formation positions of the chip connection pads 8.

Au film, Pd film and an Ni film may be formed on each of the chip connection pads 8 in order to improve bonding property to the bump 12 when the semiconductor element 11 is flip-chip bonded. The insulating film 9 formed on the first board 2 is formed only on the upper surface of the first board 2 (the formation surface of the chip connection pads 8), but may also be formed on the inner surfaces of through holes where the through electrodes 6 are provided, on the lower surface of the first board 2 bonded to a wiring member 30 (insulating member 20), and a side surface of the first board 2.

The via connection pads 10 are formed on the lower surface of the silicon substrate 4. The via connection pads 10 are connected to the through electrodes 6. Therefore, the via connection pads 10 are electrically connected to the chip connection pads 8 through the through electrodes 6 and the upper wirings 7. The respective formation positions of the via connection pads 10 correspond to the respective formation positions of connection vias 18X provided in the second board 3 described later.

To manufacture the first board 2, a plurality of first boards 2 are formed from a single wafer at the same time and then the wafer is separated into plural pieces so that the first boards 2 are produced. Since a large number of the first boards 2 can be produced from the single wafer, the manufacturing cost of the first board 2 can be reduced.

Each of the wirings formed on the first board 2 (the upper wiring 7, the chip connection pads 8, the via connection pads 10) is formed using fine process such as photolithography technology. That is, each wiring 7, 8, 10 is formed using the manufacturing technique of the semiconductor element 11. Thus, the pad pitches of the chip connection pads 8 can be formed so as to become equal to the electrode pitches of electrodes (not shown) provided in the semiconductor element 11.

Next, the second board 3 will be described. The second board 3 is a coreless substrate and is a rectangular board having a size of 40 mm×40 mm, for example, when viewed from the top. Therefore, the first board 2 is smaller than the second board 3.

The second board 3 includes a wiring member 30 formed by building-up an insulating member 20, insulating layers 20a and 20b, and wiring layers 18a to 18c. The insulating member 20 is provided on the surface of the wiring member 30. The insulating member 20 is a film member made of a resin such as epoxy and has a thickness of 30 μm, for example.

The above-described first board 2 is fixed to the insulating member 20 with adhesion. An agent having a thermosetting property may be used as an adhesive. If the first board 2 is an organic substrate, the same material as the built-up material that is a material of the organic substrate can be used as an adhesive.

The connection via 18X constituting a part of the first wiring layer 18a is formed at a predetermined position of the insulating member 20. The tip (the upper end portion in the figure) of the connection via 18X is formed by plating directly on the via connection pad 10, which is formed on the first board 2, as described later.

The first wiring layer 18a (connection via 18X) is formed of Cu, for example. Likewise, the second wiring layer 18b and the third wiring layer 18c are also formed of Cu, for example. The insulating layers 20a and 20b are formed of a resin material having insulation properties such as epoxy-based resin or polyimide-based resin.

The second wiring layer 18b and the third wiring layer 18c are formed integrally with vias 18Y and 18Z that pass through the insulating layers 20a and 20b. Therefore, the first to third wiring layers 18a to 18c are interlayer-connected through the connection via 18X and the vias 18Y and 18Z.

A solder resist 22 is formed on a back surface of the wiring member 30 and an opening 22X is provided in the solder resist 22. The third wiring layer 18c used as an external connection terminal is exposed from the opening 22X.

The first board 2 is mounted on the second board 3. Here, attention is focused on the connection structure between each via connection pad 10 and each connection via 18X in a state where the first board 2 is mounted on the second board 3.

In the exemplary embodiment, the connection via 18X and the via connection pad 10 are directly connected at the position where the first board 2 and the second board 3 are connected. Specifically, the connection via 18X is grown using an electroplating method on the via connection pad 10, whereby the connection via 18X and the via connection pad 10 are directly connected.

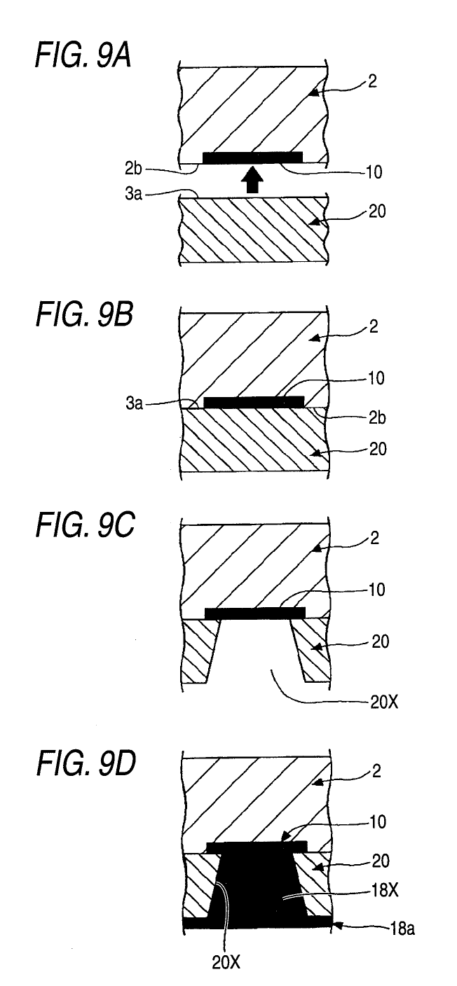

FIG. 9D shows the connection position between the connection via 18X and the via connection pad 10 in an enlarged manner. The connection via 18X is formed using an electroplating method on the via connection pad 10, whereby the connection via 18X is formed integrally and continuously on the via connection pad 10 as shown in the figure.

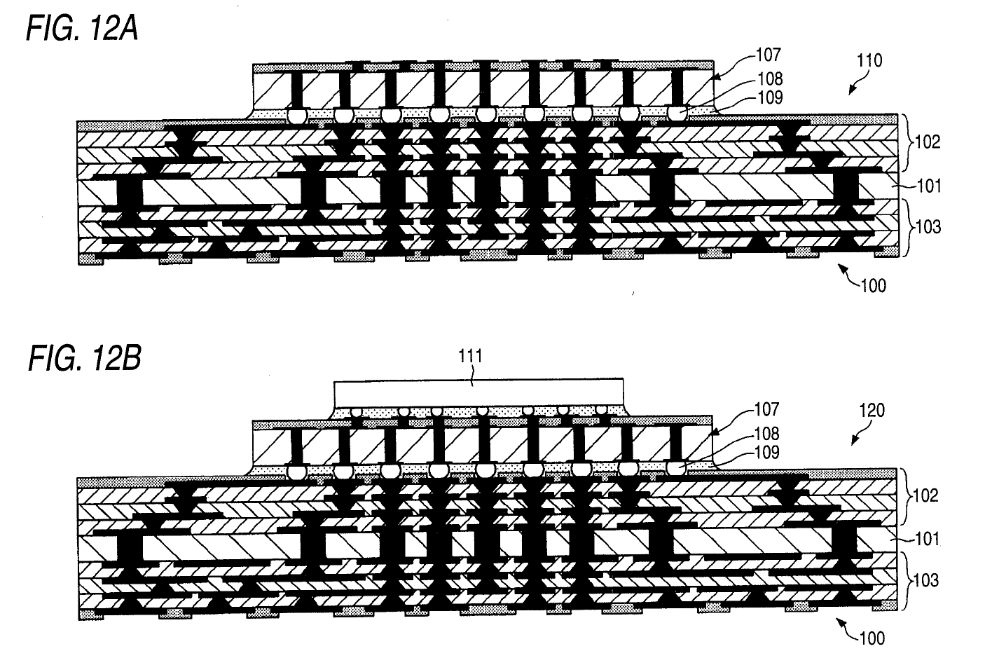

Thus, the connection via 18X and the via connection pad 10 are directly connected, whereby the bump 108 and the underfill resin 109 required for the relatd art wiring board 110 (see FIG. 12) can be made unnecessary. Accordingly, the wiring board 1A according to the exemplary embodiment makes it possible to decrease the number of components and reduce the manufacturing cost.

As described above, in a region except for the connection position where each connection via 18X and each via connection pad 10 are connected, a lower surface 2b of the first board 2 and an upper surface 3a of the second board 3 are bonded to each other with an adhesive. Thus, the mechanical connection of the first board 2 and the second board 3 can be secured.

FIG. 2 shows the semiconductor device 50 having the above wiring board 1A, and shows an example in which the semiconductor device 50 is mounted on a mother board 51 via solder balls 52.

The semiconductor element 11 is flip-chip bonded to the chip connection pads 8 formed on an upper surface 2a of the first board 2. At this time, the first board 2 is formed by fine process, so that the pitches of the chip connection pads 8 can be made to correspond to the electrode pitches of the semiconductor element 11. Therefore, even the high density semiconductor element 11 can be mounted reliably on the first board 2.

The semiconductor device 50 is mounted on the mother board 51. At this time, the pitches of the pads formed on the mother board 51 are wider than those of the electrodes formed on the semiconductor element 11. In the exemplary embodiment, however, the second board 3 having a larger shape on the top view than the first board 2 on which the semiconductor element 11 is mounted is connected to the mother board 51. Since the second board 3 is formed by building up the insulating layers 20a and 20b and the wiring layers 18a to 18c as mentioned above, the third wiring layer 18 (used as external connection terminal) can be formed so as to correspond to the pad pitches of the mother board 51. Accordingly, it is made possible to reliably mount even the semiconductor device 50, on which the semiconductor element 11 is mounted, on the mother board 51. Therefore, the connection reliability between the semiconductor device 50 and the mother board 51 can be improved.

Next, various modified examples of the wiring board 1A described above will be described.

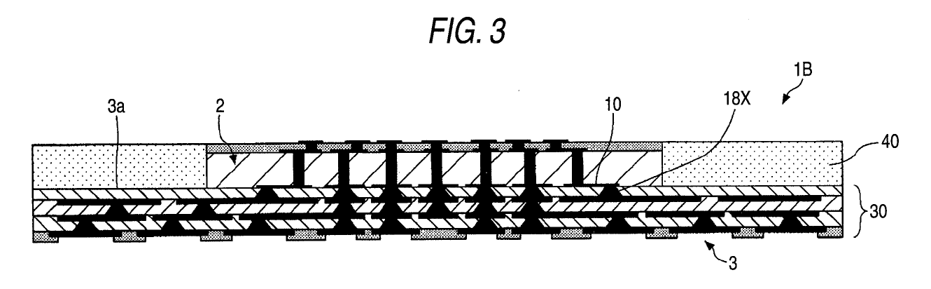

FIGS. 3 to 6 are cross-sectional views showing first to fourth modified examples of the wiring board according to the exemplary embodiment of the present invention. The same components as those described in FIGS. 1 and 2 are denoted by the same reference numerals and thus their descriptions will be omitted herein.

According to the wiring board 1A of the exemplary embodiment, the size of the first board 2 when viewed from the top view is smaller than that of the second board 3 as described above and the first board 2 is provided at the center position of the second board 3. Thus, an exposure portion of the upper surface 3a of the second board 3 occurs around the first board 2. In wiring boards 1B to 1D shown in FIGS. 3 to 5, a seal resin 40 is provided at the exposure portion of the upper surface 3a of the second board 3.

FIG. 3 shows the wiring board 1B according to the first modified example. In the wiring board 1B shown in the figure, the seal resin 40 is provided at the exposure portion of the upper surface 3a of the second board 3. The seal resin 40 is provided on the wiring member 30, whereby the seal resin 40 functions as a stiffener. Thus, according to the wiring board 1B of the modified example, the mechanical strength of the second board 3 can be enhanced and occurrence of warpage or deformation of the wiring board 1B can be prevented.

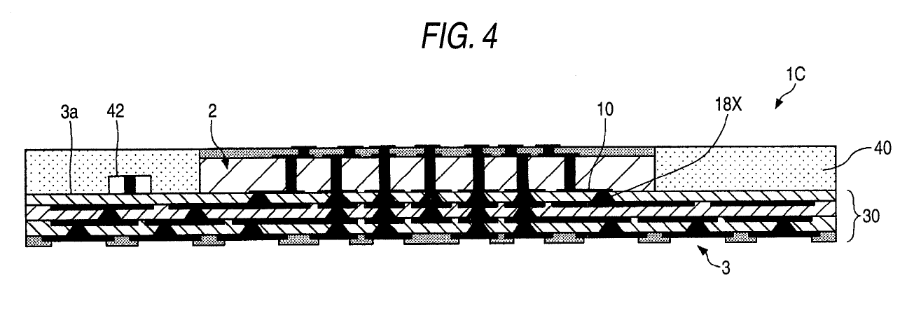

FIG. 4 shows the wiring board 1C according to the second modified example. In the wiring board 1C according to the modified example, an electronic component is provided on the exposure portion of the upper surface 3a of the second board 3, thereby providing the wiring board 1C with multiple functions.

In the modified example, a chip capacitor 42 is disposed on the second board 3. However, the electronic component disposed on the second board 3 is not limited to the chip capacitor 42 and any other electronic component (such as an active element or a passive element) can also be disposed. In the modified example, the chip capacitor 42 is sealed with seal resin 40, thereby providing high reliability, but it is also possible to use no seal resin 40.

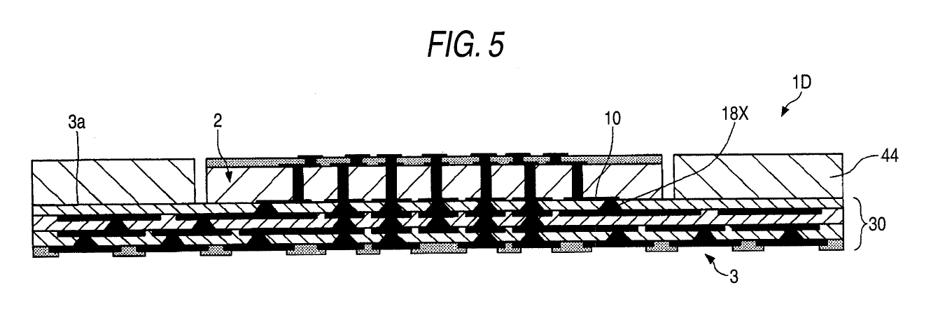

FIG. 5 shows the wiring board 1D according to the third modified example. In the wiring board 1D according to the modified example, a frame-shaped stiffener 44 made of metal is provided on the exposure portion of the upper surface 3a of the second board 3 to mechanically reinforce the second board 3. The stiffener 44 made of metal is provided as in the modified example, whereby the second board 3 can be reinforced more reliably and the reliability of the wiring board 1D can be enhanced.

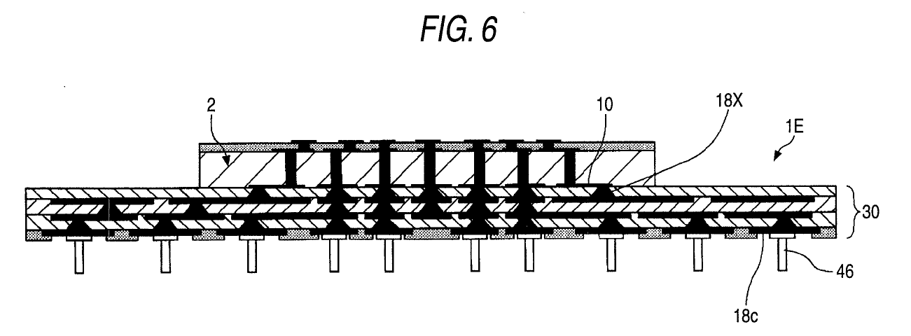

FIG. 6 shows the wiring board 1E according to the fourth modified example. In the example previously described with reference to FIG. 2, the solder balls 52 are used to mount the wiring board 1A on the mother board 51. In the wiring board 1E according to the fourth modified example, pins 46 are provided on third wiring layer 18c and are used to mount the wiring board 1E on the mother board 51. Thus, external connection terminals to be provided on the third wiring layer 18c are selected, if required. Therefore, a mode to mount the second board 3 on the mother board 51 can be selected from among various modes.

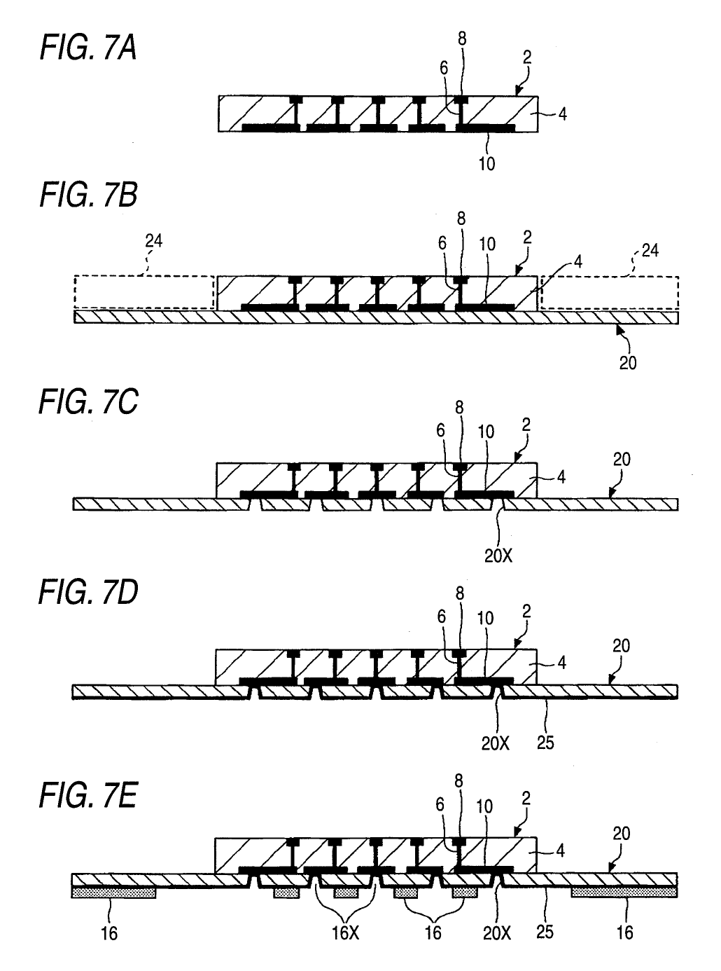

Next, a method of manufacturing the wiring board according to the exemplary embodiment of the present invention will be described with reference to FIGS. 7A to 10D.

In the following description, a method of manufacturing the wiring board 1A shown in FIG. 1 is taken as an example. Components corresponding to those previously described with reference to FIGS. 1 and 2 are denoted by the same reference numerals in FIGS. 7A to 10D and their description will be omitted herein. Further, for the convenience of the figures, a part of the wiring board 1A shown in FIG. 1 is omitted.

To begin with, to manufacture the wiring board 1A, a first board 2 is provided as in FIG. 7A. The first board 2 has through electrodes 6 that pass through a silicon substrate 4 and chip connection pads 8 are formed on the upper surface and via connection pads 10 are formed on the lower surface as mentioned above. A large number of silicon substrates 4 are taken out from one wafer. That is, a number of first boards 2 are formed on one wafer through fine process such as photolithography technology, and then are divided into pieces by dicing, thereby manufacturing the first boards 2. The first board 2 thus manufactured is at a low cost and has high precision.

An insulating member 20 is provided on the first board 2 as shown in FIG. 7B. The insulating member 20 is a film member formed of a resin such as epoxy as mentioned above and is bonded onto the first board 2 with an adhesive such as an ultraviolet curing property, for example.

FIGS. 9A to 9D are views showing the proximity of one via connection pad 10 in an enlarged manner. FIG. 9A shows a state before the first board 2 is bonded to the insulating member 20 and FIG. 9B shows a state in which the first board 2 is bonded to the insulating member 20. As the first board 2 is bonded to the insulating member 20, the connection pad 10 is completely covered with the insulating member 20.

The insulating member 20 has a wider area than the first board 2 when viewed from the top. The area of the insulating member 20 is set depending on the number of terminals of the wring board 1A connected to a mother board 51, the pad pitches of the mother board 51, etc.

Also, the insulating member 20 may be flexibly deformed. Thus, a reinforcing member 24 (indicated by the dashed line in the figure) may be provided to enhance the mechanical strength of the insulating member 20 before or after the first board 2 is bonded to the insulating member 20.

When the first board 2 is bonded to the insulating member 20 as described above, subsequently drilling is performed so as to form first via holes 20X in the insulating member 20. The forming position of the first via holes 20X are set to the positions corresponding to the via connection pads 10 formed on the first board 2. Although laser beam machining can be used, for example, as a forming method of the first via holes 20X, any other machining method may be used if highly accurate hole machining can be performed. In laser beam machining, cleaning treatment (desmear treatment) for smear removal is performed as required. At this time, desmear treatment may be performed with the first board 2 while the first board 2 is protected by performing treatment of masking, etc., for the first board 2.

FIGS. 7 C and 9 C show a state in which the first via hole 20X is formed. As the first via hole 20X is formed, the first via hole 20X communicates with the via connection pad 10 at the forming position of the first via hole 20X and therefore the via connection pad 10 is exposed.

When the first via hole 20X is formed as described above, a seed layer 25 is formed on the rear surface of the insulating member 20 (surface opposite to the surface to which the first board 2 is bonded), as shown in FIG. 7D. The seed layer 25 is copper, for example, and is formed in a thickness of 0.5 μm (electroless plating) using electroless plating or sputtering. In forming Cu as the seed layer 25 by sputtering, Ti may be formed before Cu is grown as pre-treatment.

Subsequently, a resist film 16 is formed on the insulating member 20 formed with the seed layer 25. For example, a dry film can be used as the resist film 16. Patterning treatment is performed for the resist film 16 to form openings 16X in predetermined positions (positions corresponding to the forming positions of a first wiring layer 18a described later) as shown in FIG. 7E. The openings 16X may be previously formed in the resist film 16 shaped like a dry film and the resist film 16 formed with the openings 16X may be provided on a support 10.

Next, electrolytic Cu plating is performed using the seed layer 25 as a plating feeding layer. Accordingly, a connection via 18X is formed on the via connection pad 10 and in the first via hole 20X, and also a first wiring layer 18a is formed on the surface of the insulating member 20.

At this time, since the connection via 18X is formed directly on the via connection pad 10 by plating, the connection via 18X is formed directly on the via connection pad 10. The expression “the connection via 18X is formed directly on the via connection pad 10” means that the connection via 18X is formed integrally and continuously on the via connection pad 10.

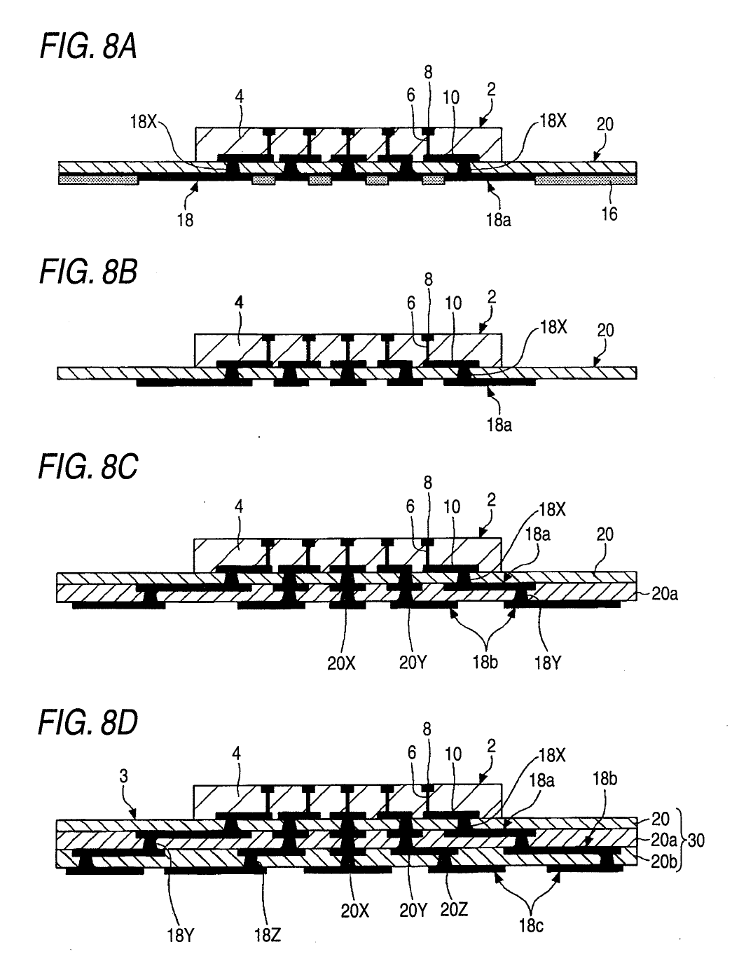

When the connection via 18X and the first wiring layer 18a are thus formed, then the resist film 16 is removed as shown in FIG. 8B.

Subsequently, the connection via 18X and the first wiring layer 18a are formed and a first insulating layer 20a is formed to cover the insulating member 20. A resin material such as epoxy-based resin, polyimide-based resin, etc., is used as a material of the first insulating layer 20a. As an example of a forming method of the first insulating layer 20a, a resin film is laminated on the insulating member 20 and then is harden by thermal treatment at a temperature of 130° C. to 150° C. while the resin film is pressed, whereby the first insulating layer 20a can be provided.

Next, a first via hole 20Y is formed in the first insulating layer 20a formed on the insulating member 20 using laser beam machining, etc., so as to expose the first wiring layer 18a. The first insulating layer 20a may be formed by patterning a photosensitive resin film using photolithography.

Subsequently, a second wiring layer 18b connected through the first via hole 20Y is formed in the first wiring layer 18a formed on the insulating member 20. The second wiring layer 18b is made of copper (Cu) and is formed on the first insulating layer 20a. The second wiring layer 18b is formed by a semi-additive process, for example.

More particularly, firstly, a Cu seed layer (not shown) is formed in the first via hole 20Y and on the first insulating layer 20a by electroless plating or sputtering and then a resist film (not shown) having an opening corresponding to the second wiring layer 18b is formed. Next, a Cu layer pattern (not shown) is formed in the opening of the resist film by electrolytic plating using the Cu seed layer as a plating feeding layer.

Subsequently, the resist film is removed and then the Cu seed layer is etched with the Cu layer pattern as a mask, thereby providing the second wiring layer 18b. FIG. 8C shows a state in which the second wiring layer 18b is formed. In addition to the semi-additive process, any of various wiring formation methods such as a subtractive process can be adopted as a forming method of the second wiring layer 18b.

Next, as shown in FIG. 8D, similar steps to those described above are repeatedly performed, whereby a second insulating layer 20b is formed on the insulating member 20a to cover the second wiring layer 18b and then a third via hole 20Z is formed in the portion of the second insulating layer 20b on the second wiring layer 18b. Further, a third wiring layer 18c connected to the second wiring layer 18b through the third via hole 20Z is formed.

Subsequently, a solder resist 22 having an opening 22X is formed (not shown in FIG. 8; see FIG. 1) at a predetermined position on the second insulating layer 20b and the third wiring layer 18c. Accordingly, a wiring member 3 in which the insulating member 20, the insulating layers 20a and 20b, and the wiring layers 18a to 18c are built up is manufactured and the second board 3 is also complete.

The wring board 1A having a structure in which the first board 2 is mounted on the second board 3 is thus manufactured. In the above-described exemplary embodiment, the three build-up wiring layers (first to third wiring layers 18a to 18c) are formed on the insulating member 20, but n build-up wiring layers (where n is an integer of one or more) may be formed.

As described above, according to the method of manufacturing the wiring board 1A of the exemplary embodiment of the present invention, the connection process of the first board 2 and the second board 3 is performed automatically in the step of forming the wiring member 30 directly on the insulating member 20 bonded to the first board 2 using the semi-additive process and build-up method. That is, each via connection pad 10 and each connection via 18X positioned in the boundary portion between the first board 2 and the second board 3 are formed directly (integrally and continuously) as the connection via 18X is formed on the via connection pad 10 by plating.

Therefore, the first board 2 and the second board 3 can be connected without using a bump or an underfill resin required formerly. As a facility for connecting the via connection pads 10 and the intersubstrate connection vias 18X, the facility used in build-up forming of the wiring member 30 can be used as it is. Therefore, the need for the facility used only to connect the first board 2 and the second board 3 can be eliminated and the facility cost can be reduced.

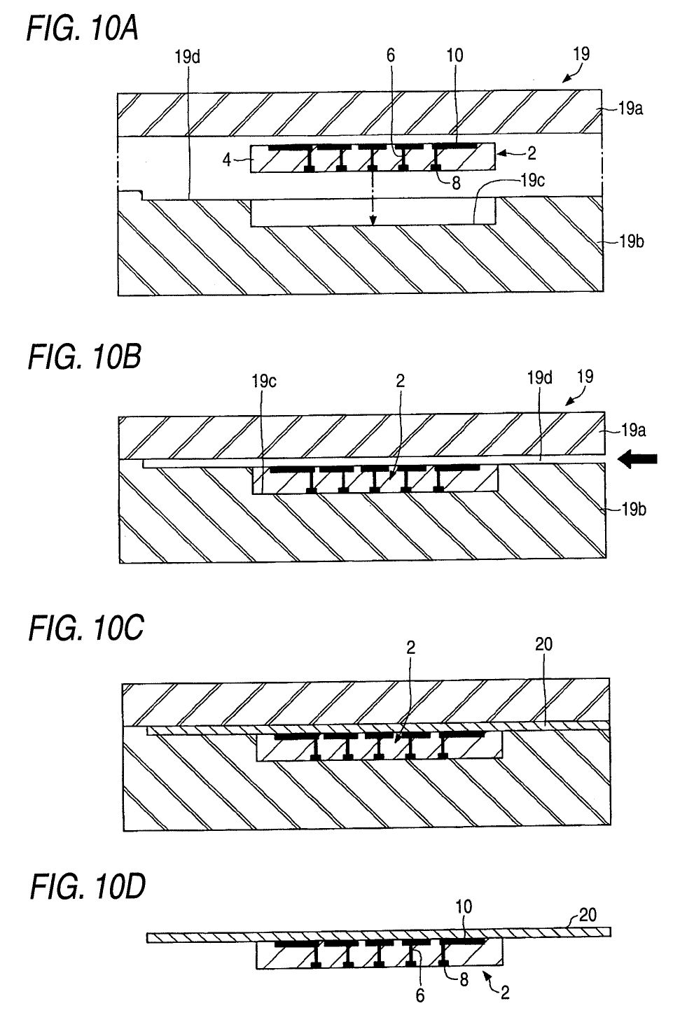

In the method of manufacturing the wiring board 1A according to the above-described exemplary embodiment of the present invention, a film member made of a resin is used as the insulating member 20 and the insulating member 20 is bonded to the first board 2. However, the insulating member 20 is not limited to a film member made of a resin and can also be formed by molding a resin. A modified example of forming the insulating member 20 using a mold will be described with reference to FIGS. 10A to 10D.

FIG. 10A shows a mold 19 used in the modified example. The mold 19 is made up of an upper mold (die) 19a and a lower mold (die) 19b. The upper mold 19a has a flat shape and functions as a lid. The lower mold 19b is formed with a first cavity part 19c in which the first board 2 is placed and a second cavity part 19d used to form the insulating member 20.

In molding the insulating member 20, the first board 2 is placed in the first cavity part 19c of the lower mold 19b and the upper mold 19a is placed over the lower mold 19b, as shown in FIG. 10B. Accordingly, the second cavity 19d corresponding to the insulating member 20 is formed between the upper mold 19a and the lower mold 19b.

As shown in FIG. 10C, a resin is poured into the second cavity part 19d, thereby molding the insulating member 20. At the molding time, the insulating member 20 is bonded to the first board 2. Thus, to perform mold release, they can be taken out from the mold 19 in a state that the insulating member 20 is bonded to the first board 2. Thus, the insulating member 20 is molded using the mold 19, whereby the highly accurate insulating member 20 can be formed.

In the modified example described above, the cavity 19c formed in the lower mold 19b is shaped so as to correspond to the shape of the first board 2 and the shape of the insulating member 20. However, the insulating member 20 may be molded using a support plate having an outer shape which is the same as the shape of the insulating member 20 and adapted to allow the first board 2 to be placed in the center.

According to the configuration, the first board 2 is placed in the mold 19 to be surrounded by the support plate and thus the cavity of the mold 19 may be made to correspond to the outer shape of the insulating member 20. Therefore, the shape of the cavity 19d formed in the lower mold 19b can be simplified and the mold cost can be reduced and the releasability of the insulating member 20 from the mold 19 can also be enhanced.

While the present invention has been shown and described with reference to certain exemplary embodiments thereof, it will be understood by those skilled in the art that various changes in form and details may be made therein without departing from the spirit and scope of the invention as defined by the appended claims. It is aimed, therefore, to cover in the appended claim all such changes and modifications as fall within the true spirit and scope of the present invention.

1-6. (canceled)

7. A method of manufacturing a wiring board, the method comprising:
(a) preparing a first board having a pad;
(b) bonding an insulating member on the first board with an adhesive, wherein a size of the insulating member is larger than that of the first board, when viewed from the top, and wherein the insulting member is a resin film;
(c) forming a via hole in a portion of the insulating member corresponding to the pad, and forming a via in the via hole on the pad by continuously and integrally growing the via on the pad by electroplating such that the via is directly connected to the pad; and
(d) repeatedly forming a wiring layer and an insulating layer on the insulating member in which the via is formed, thereby forming a second board.

8. (canceled)

9. The method of claim 7, wherein step (b) comprises:
placing the first board in a mold; and
forming the insulating member on the first board by molding a resin.

10. (canceled)

11. The method of claim 7, wherein the first board is made of silicon.

12. The method of claim 7, wherein step (b) comprises:
providing a reinforcing member to surround a periphery of the first board.
